(19) United States
(12) Patent Application Publication
(10) Pub. No.: US 2026/0126496 A1
(43) Pub. Date: May 7, 2026

(54) DEVICE FOR DIAGNOSING A STATE OF A BATTERY AND METHOD THEREOF

(71) Applicants: HYUNDAI MOTOR COMPANY, Seoul (KR); KIA CORPORATION, Seoul (KR)

(72) Inventor: Yo Han Baek, Hwaseong-si (KR)

(73) Assignees: HYUNDAI MOTOR COMPANY, Seoul (KR); KIA CORPORATION, Seoul (KR)

(21) Appl. No.: 19/062,946

(22) Filed: Feb. 25, 2025

(30) Foreign Application Priority Data
Nov. 4, 2024 (KR) 10-2024-0154580

(51) Int. Cl. G01R 31/3842; G01R 31/396; H01M 10/42

(52) U.S. Cl. CPC G01R 31/3842; G01R 31/396; H01M 10/4285

(57) ABSTRACT

A device and a method for diagnosing a state of a battery are capable of accurately diagnosing the state of a battery and the state of each cell constituting the battery by: monitoring the charging current of the battery to determine a diagnosing time interval in which a preset current change value is maintained; determining a first voltage and a second voltage in the diagnosing time interval; determining a time taken for each cell voltage of each cell of the battery to reach the second voltage from the first voltage within the diagnosing time interval; and diagnosing the state of the battery based on the time corresponding to each cell.

### CROSS-REFERENCE TO RELATED APPLICATION

This application claims the benefit of and priority to Korean Patent Application No. 10-2024-0154580, filed in the Korean Intellectual Property Office on Nov. 4, 2024, the entire contents of which are incorporated herein by reference.

### TECHNICAL FIELD

The present disclosure relates to a technology for diagnosing the state of a battery installed in an electric vehicle with high accuracy.

### BACKGROUND

In general, an electric vehicle, which is a vehicle driven by electric energy, is equipped with a battery including a plurality of battery cells that store electric energy. Such battery cells convert chemical energy into electrical energy to supply electrical energy (discharge), or convert electrical energy supplied from an outside into chemical energy to store it (charge).

Because an electric vehicle is driven using electrical energy stored in a battery as a power source, the performance of the vehicle is significantly affected by the performance of the battery. Therefore, in order to improve the performance of an electric vehicle, it is required to manage the battery to maximize the performance.

In recent years, because battery cells with excellent performance are used to improve the power source of a vehicle, and the number of battery cells increases gradually, it is more required to manage a battery. Such battery management is generally performed by a battery management system (BMS).

The battery management system measures cell state information including a voltage, a current, a temperature, and the like of a battery cell from a battery module provided in an electric vehicle, uses the cell state information and option values for controlling battery cells to manage the battery cells, and performs cell balancing to maintain balance between the battery cells.

The cell balancing is one of the control operations of a battery management system that equalizes the voltages or charge amounts of battery cells. Each battery cell of a battery module may have differences in electrical characteristics even when the battery cells are manufactured under the same manufacturing conditions and environment. Each battery cell of a battery module may also have differences in electrical characteristics even when the battery cells are mounted and operated in an electric vehicle.

Due to such differences in electrical characteristics, even when battery cells are charged and discharged with the same current, voltage imbalance or residual charge imbalance may occur between interconnected battery cells, and the voltage imbalance or residual charge imbalance between battery cells may cause the available voltage range of battery cells to decrease or the charging and discharging cycle to be shorter.

Recently, fires have occurred frequently in electric vehicles while charging their batteries. This is caused by an abnormal state of the battery. In order to prevent such fires, technology that can accurately diagnose the state of a battery installed in an electric vehicle is required.

The matters described in this background section are intended to promote an understanding of the background of the disclosure and may include matters that are not already known to those of ordinary skill in the art.

### SUMMARY

In some cases, for diagnosing the state of a battery, the voltage change of the battery is monitored in a first transition section (or time interval) from a closed circuit voltage (CCV) to an open circuit voltage (OCV) and a second transition section (or time interval) from the OCV to the CCV, and the state of the battery is diagnosed based on the monitoring result.

However, because the voltage change of the battery is to be monitored only during the first and second transition sections, which are very short in time, it is impossible to sufficiently monitor the voltage change of the battery. Therefore, the battery state may not be diagnosed with high accuracy.

The present disclosure has been made to solve the above-mentioned problems while advantages achieved by the prior art are maintained intact.

One aspect of the present disclosure provides a device for diagnosing a state of a battery and a method thereof, which are capable of accurately diagnosing not only the state of a battery but also the state of each cell constituting the battery by: monitoring the charging current of the battery to determine or detect a current section (i.e., a diagnosing time interval) in which a preset current change value is maintained; determining a first voltage and a second voltage in the current section; determining or detecting the time taken for each cell voltage of each cell of a plurality of cells of the battery to reach the second voltage from the first voltage within the current section; and diagnosing the state of the battery based on the time corresponding to each cell.

Another aspect of the present disclosure provides a device for diagnosing a state of a battery and a method thereof, which are capable of accurately diagnosing not only the state of a battery but also the state of each cell constituting the battery by: monitoring the charging current of the battery to detect or determine a current section in which a preset current change value is maintained; determining the first voltage and the second voltage in the current section; detecting or determining the time taken for each cell voltage of each cell of a plurality of cells of the battery to reach the second voltage from the first voltage within the current section, and determining the standard deviation (σ) of times corresponding to the plurality of cells; and diagnosing the state of the battery based on the number of cells included in a threshold section (i.e., a threshold range) (e.g., less than −2σ and greater than 2σ).

Still another aspect of the present disclosure provides a device for diagnosing a state of a battery and a method thereof, which are capable of accurately diagnosing not only the state of a battery but also the state of each cell constituting the battery by: monitoring the charging current of the battery to detect or determine at least one current section (or a plurality of current sections) in which a preset current change value is maintained; determining the first voltage and the second voltage in each current section; detecting or determining the time taken for each cell voltage of each cell to reach the second voltage from the first voltage within each current section; and diagnosing the state of the battery based on the time corresponding to each cell in each current section.

Still another aspect of the present disclosure provides a device for diagnosing a state of a battery and a method thereof, which are capable of accurately diagnosing not only the state of a battery but also the state of each cell constituting the battery by: monitoring the charging current of the battery to detect or determine at least one current section (or a plurality of current sections) in which a preset current change value is maintained; determining the first voltage and the second voltage in each current section; detecting or determining the time taken for each cell voltage to reach the second voltage from the first voltage within each current section, and determining a standard deviation (σ) of times corresponding to the plurality of cells of the battery in each current section; and diagnosing the state of the battery based on the number of cells included in a threshold section (e.g., less than −2σ and greater than 2σ).

Still another aspect of the present disclosure provides a device for diagnosing a state of a battery and a method thereof, which are capable of accurately diagnosing not only the state of a battery but also the state of each cell of a plurality of cells constituting the battery by: monitoring the charging current of the battery to detect or determine a current section in which a preset current change value is maintained; determining the maximum value (i.e., the highest value) among the minimum voltages of the plurality of cells within the current section as the first voltage of the current section; determining the minimum value (i.e., the lowest value) among the maximum voltages of the plurality of cells within the current section as the second voltage of the current section; detecting or determining the time taken for each cell voltage of the battery to reach the second voltage from the first voltage within the current section; and diagnosing the state of the battery based on the time corresponding to each cell.

Still another aspect of the present disclosure provides a device for diagnosing a state of a battery and a method thereof, which are capable of accurately diagnosing not only the state of a battery but also the state of each cell constituting the battery by: monitoring the charging current of the battery to detect or determine a current section in which a preset current change value is maintained; determining the first voltage and the second voltage as a voltage range of the current section; dividing the voltage range into a plurality of voltage sections (i.e., into a plurality of voltage segments); determining the minimum voltage and the maximum voltage in each voltage section; detecting or determining the time taken for each cell voltage of each cell of the battery to reach the maximum voltage from the minimum voltage within each voltage section; and diagnosing the state of the battery based on the time corresponding to each cell.

The technical problems to be solved by the present disclosure are not limited to the aforementioned problems, and any other technical problems not mentioned herein should be clearly understood from the following description by those having ordinary skill in the art to which the present disclosure pertains. Also, it may be easily understood that the objects and advantages of the present disclosure may be realized by the means and combinations thereof recited in the claims.

According to one aspect of the present disclosure, a device for diagnosing a state of a battery includes a current sensor that detects or determines a charging current of the battery, a voltage sensor that detects or determines a voltage of the battery, and a controller. The controller monitors the charging current of the battery to detect or determine a current section in which a preset current change value is maintained, determines a first voltage and a second voltage as a voltage range of the current section, detects or determines a time taken for each cell voltage of each cell of a plurality of cells of the battery to reach the second voltage from the first voltage within the current section, and diagnoses the state of the battery based on a time corresponding to each cell.

According to an embodiment, the controller may detect or determine a maximum voltage and a minimum voltage of each cell in the current section, determine a maximum, or highest, value among minimum voltages of cells as the first voltage of the current section, and determine a minimum, or lowest, value among maximum voltages of the cells as the second voltage of the current section.

According to an embodiment, the controller may determine a standard deviation of times corresponding to cells and diagnose the state of the battery based on the standard deviation.

According to an embodiment, the controller may detect or determine at least one current section, determine a first voltage and a second voltage in each current section of the at least one current section, detect or determine a time taken for each cell voltage to reach the second voltage from the first voltage within each current section of the at least one current section, and diagnose the state of the battery based on the time corresponding to each cell in each current section of the at least one current section.

According to an embodiment, the controller may determine a standard deviation of times corresponding to the plurality of cells in each current section and diagnose the state of the battery based on the standard deviation of each current section.

According to an embodiment, the controller may divide the voltage range into a plurality of voltage sections, detect or determine a time (i.e., a voltage segment time) taken for each cell voltage to reach a maximum voltage from a minimum voltage within each voltage section, and diagnose the state of the battery based on the time corresponding to each cell in each voltage section.

According to an embodiment, the controller may determine a standard deviation of times corresponding to the plurality of cells in each voltage section and diagnose the state of the battery based on the standard deviation of each voltage section.

According to an embodiment, the controller may monitor the charging current of the battery in all sections (i.e., time intervals) other than a state transition section (i.e., a time interval of a sate transition) between a closed circuit voltage (CCV) and an open circuit voltage (OCV).

According to an embodiment, the controller may detect or determine a constant current section (i.e., a time interval of a constant current) in which the current change value is 0 (zero) as the current section (i.e., the diagnosing time interval).

According to another aspect of the present disclosure, a method of diagnosing a state of a battery includes: detecting or determining, by a controller, a current section in which a preset current change value is maintained, by monitoring a charging current of the battery; determining, by the controller, a first voltage and a second voltage as a voltage range of the current section; detecting or determining, by the controller, a time taken for each cell voltage of each cell of a plurality of cells of the battery to reach the second voltage from the first voltage within the current section; and diagnosing, by the controller, the state of the battery based on the time corresponding to each cell.

According to an embodiment, determining the first voltage and the second voltage may include detecting or determining a maximum voltage and a minimum voltage of each cell in the current section, determining a maximum value among minimum voltages of the plurality of cells as the first voltage of the current section, and determining a minimum value among maximum voltages of the cells as the second voltage of the current section.

According to an embodiment, diagnosing the state of the battery may include determining a standard deviation of times corresponding to the plurality of cells, and diagnosing the state of the battery based on the standard deviation.

According to an embodiment, diagnosing the state of the battery may include diagnosing the state of the battery based on a time corresponding to each cell in each current section of a plurality of current sections (i.e., in each diagnosing time interval of a plurality of diagnosing time intervals) based on detecting or determining the plurality of current sections.

According to an embodiment, diagnosing the state of the battery may include determining a standard deviation of times corresponding to each cell in each current section, and diagnosing the state of the battery based on the standard deviation of each current section.

According to an embodiment, the diagnosing of the state of the battery may include diagnosing the state of the battery based on a time (i.e., a voltage segment time) corresponding to each cell in each of a plurality of voltage sections based on dividing the voltage range into the plurality of voltage sections.

According to an embodiment, diagnosing the state of the battery may include determining a standard deviation of times corresponding to the plurality of cells in each voltage section, and diagnosing the state of the battery based on the standard deviation of each voltage section.

According to an embodiment, detecting or determining the current section may include monitoring the charging current of the battery in all sections (i.e., all time intervals) other than a state transition section (i.e., a time interval of a state transition) between a closed circuit voltage (CCV) and an open circuit voltage (OCV).

According to an embodiment, detecting or determining the current section may include detecting or determining a time interval of a constant current section in which the current change value is 0 (zero) as the current section (i.e., the diagnosing time interval).

### BRIEF DESCRIPTION OF THE DRAWINGS

The above and other objects, features and advantages of the present disclosure should be more apparent from the following detailed description taken in conjunction with the accompanying drawings:

FIG. 1 is a diagram illustrating a device for diagnosing a state of a battery according to an embodiment of the present disclosure;

FIG. 2 is a diagram illustrating an example of a section in which a controller provided in a device for diagnosing a state of a battery according to an embodiment of the present disclosure monitors the charging current of a battery;

FIG. 3 is a diagram illustrating an example of a current section detected by a controller provided in a device for diagnosing a state of a battery according to an embodiment of the present disclosure;

FIG. 4A is a diagram illustrating the voltage of each cell constituting a battery within current section C1;

FIG. 4B is a diagram illustrating the voltage of each cell constituting a battery within current section C2;

FIG. 4C is a diagram illustrating the voltage of each cell constituting a battery within current section C3;

FIG. 4D is a diagram illustrating the voltage of each cell constituting a battery within current section C4;

FIG. 4E is a diagram illustrating the voltage of each cell constituting a battery within current section C5;

FIG. 4F is a diagram illustrating the voltage of each cell constituting a battery within current section C6;

FIG. 5 is a diagram illustrating an operation of determining the minimum voltage (i.e., a first voltage) and the maximum voltage (i.e., a second voltage) in current section C1 by a controller provided in a device for diagnosing a state of a battery according to an embodiment of the present disclosure;

FIG. 6 is a diagram illustrating a result of dividing the voltage range of current section C1 into a plurality of voltage sections by a controller provided in a device for diagnosing a state of a battery according to an embodiment of the present disclosure;

FIG. 7 is a diagram illustrating an example of an operation of detecting a time change value of each cell voltage by a controller provided in a device for diagnosing a state of a battery according to an embodiment of the present disclosure;

FIG. 8A is a diagram illustrating the time taken for the voltage of each cell to reach the maximum voltage from the minimum voltage in current section C1;

FIG. 8B is a diagram illustrating the time taken for the voltage of each cell to reach the maximum voltage from the minimum voltage in current section C2;

FIG. 8C is a diagram illustrating the time taken for the voltage of each cell to reach the maximum voltage from the minimum voltage in current section C3;

FIG. 8D is a diagram illustrating the time taken for the voltage of each cell to reach the maximum voltage from the minimum voltage in current section C4;

FIG. 8E is a diagram illustrating the time taken for the voltage of each cell to reach the maximum voltage from the minimum voltage in current section C5;

FIG. 8F is a diagram illustrating the time taken for the voltage of each cell to reach the maximum voltage from the minimum voltage in current section C6;

FIG. 9 is a diagram illustrating cells classified by grade by a controller provided in a device for diagnosing a state of a battery according to an embodiment of the present disclosure;

FIG. 10 is a flowchart illustrating a method of diagnosing a state of a battery according to an embodiment of the present disclosure; and

FIG. 11 is a block diagram illustrating a computing system for executing a method of diagnosing a state of a battery according to an embodiment of the present disclosure.

### DETAILED DESCRIPTION

Hereinafter, some embodiments of the present disclosure are described in detail with reference to the drawings. In adding the reference numerals to the components of each drawing, it should be noted that the identical or equivalent component is specified by the identical numeral even when they are displayed on other drawings. Further, in describing embodiments of the present disclosure, a detailed description of the related known configuration or function has been omitted when it is determined that it interferes with the understanding of embodiments of the present disclosure.

In addition, terms, such as first, second, A, B, (a), (b) or the like may be used herein when describing components of the present disclosure. These terms are provided only to distinguish the elements from other elements, and the essences, sequences, orders, and numbers of the elements are not limited by the terms. In addition, unless defined otherwise, all terms used herein, including technical or scientific terms, have the same meanings as those generally understood by those having ordinary skill in the art to which the present disclosure pertains. The terms defined in the generally used dictionaries should be construed as having the meanings that coincide with the meanings of the contexts of the related technologies, and should not be construed as ideal or excessively formal meanings unless clearly defined in the specification of the present disclosure. When a component, controller, device, element, apparatus, or the like of the present disclosure is described as having a purpose or performing an operation, function, or the like, the component, controller, device, element, apparatus, or the like should be considered herein as being “configured to” meet that purpose or to perform that operation or function. Each component, controller, device, element, apparatus, and the like may separately embody or be included with a processor and a memory, such as a non-transitory computer readable media, as part of the apparatus.

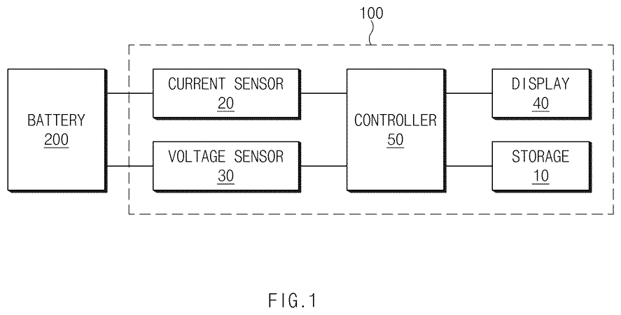

FIG. 1 is a diagram illustrating a device for diagnosing a state of a battery according to an embodiment of the present disclosure.

As illustrated in FIG. 1, a device 100 for diagnosing a state of a battery according to an embodiment of the present disclosure may include storage 10, a current sensor 20, a voltage sensor 30, a display 40, and a controller 50. In this case, depending on a scheme of implementing the device 100 for diagnosing a state of a battery according to an embodiment of the present disclosure, components may be combined with each other to be implemented as one, or some components may be omitted. In addition, the device 100 for diagnosing a state of a battery may be mounted on a vehicle or mounted on a cloud server to provide diagnostic services for multiple vehicles, or mounted on a portable diagnostic device provided at a maintenance company.

Regarding each component, first, the storage 10 may store various logic, algorithms and programs required in the process of monitoring the charging current of a battery 200 to detect a current section (i.e., a time interval, which may also be referred to herein as a diagnosing time interval) in which a current change is maintained within a preset current change value, determining a minimum voltage (i.e., a first voltage) and a maximum voltage (i.e., a second voltage) in the current section, detecting the time taken for each cell voltage of the battery 200 to reach the maximum voltage from the minimum voltage within the current section, and diagnosing the state of the battery 200 based on the time corresponding to each cell. For example, the battery 200, which is a high-voltage battery mounted on an electric vehicle, may include a plurality of cells.

The storage 10 may store various logic, algorithms and programs required in the process of monitoring the charging current of the battery 200 to detect a current section in which a preset current change value is maintained, determining the minimum voltage and the maximum voltage in the current section, detecting the time taken for each cell voltage of the battery to reach the maximum voltage from the minimum voltage within the current section, and determining the standard deviation (σ) of times corresponding to each cell, and diagnosing the state of the battery 200 based on the number of cells included in a threshold section. For example, the threshold section may include a section less than −2σ and a section greater than 2σ on a normal distribution.

The storage 10 may store various logic, algorithms and programs required in the process of monitoring the charging current of the battery 200 to detect at least one current section in which a preset current change value is maintained, determining the minimum voltage and the maximum voltage in each current section, detecting the time taken for each cell voltage of the battery 200 to reach the maximum voltage from the minimum voltage within each current section, and diagnosing the state of the battery 200 based on the time corresponding to each cell in each current section.

The storage 10 may store various logic, algorithms and programs required in the process of monitoring the charging current of the battery 200 to detect at least one current section in which a preset current change value is maintained, determining the minimum voltage and the maximum voltage in each current section, detecting the time taken for each cell voltage of the battery 200 to reach the maximum voltage from the minimum voltage within each current section, determining a standard deviation (σ) of times corresponding to each cell in each current section, and diagnosing the state of the battery 200 based on the number of cells included in a threshold section (e.g., less than −2σ and greater than 2σ).

The storage 10 may store various logic, algorithms and programs required in the process of monitoring the charging current of the battery 200 to detect a current section in which a preset current change value is maintained, determining the maximum value among the minimum voltages of each cell within the current section as the minimum voltage of the current section, determining the minimum value among the maximum voltages of each cell within the current section as the maximum voltage of the current section, detecting the time taken for each cell voltage of the battery 200 to reach the maximum voltage from the minimum voltage within the current section, and diagnosing the state of the battery 200 based on the time corresponding to each cell.

The storage 10 may store various logic, algorithms and programs required in the process of monitoring the charging current of the battery 200 to detect a current section in which a preset current change value is maintained, determining the minimum voltage and the maximum voltage as a voltage range of the current section, dividing the voltage range into a plurality of voltage sections, determining the minimum voltage and the maximum voltage in each voltage section, detecting the time taken for each cell voltage of the battery 200 to reach the maximum voltage from the minimum voltage within each voltage section, and diagnosing the state of the battery 200 based on the time corresponding to each cell.

The current sensor 20 may detect the charging current of the battery 200.

The voltage sensor 30 may detect an internal voltage of the battery.

The display 40 may display a diagnosis result of the controller 50.

The controller 50 may be electrically connected to each component and may perform overall control such that each component performs its function. The controller 50 may be implemented in the form of hardware or software, or may be implemented in a combination of hardware and software. For example, the controller 50 may be implemented as a microprocessor, but is not limited thereto.

The controller 50 may monitor the charging current of the battery 200 to detect a current section in which a preset current change value is maintained, determine the minimum voltage and the maximum voltage in the current section, detect the time taken for each cell voltage of the battery 200 to reach the maximum voltage from the minimum voltage within the current section, and diagnose the state of the battery 200 based on the time corresponding to each cell.

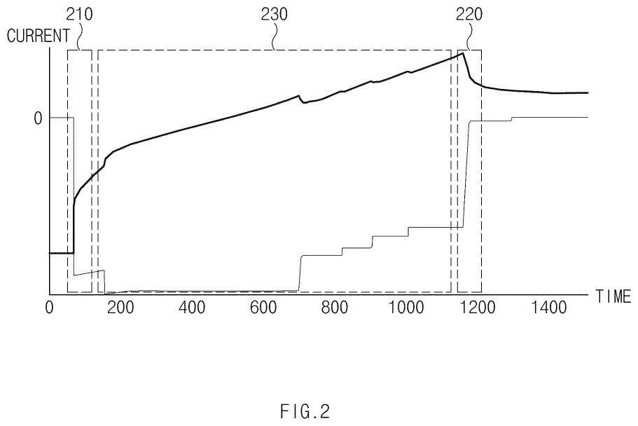

Hereinafter, the operation of the controller 50 is described with reference to FIGS. 2-9 .

FIG. 2 is a diagram illustrating an example of a section in which a controller provided in a device for diagnosing a state of a battery according to an embodiment of the present disclosure monitors the charging current of a battery.

In FIG. 2, reference numeral 210 denotes a section, or time interval, in which the transition from a closed circuit voltage (CCV) to an open circuit voltage (OCV) occurs, and reference numeral 220 denotes a section, or time interval, in which the transition from OCV to CCV occurs. Reference numerals 210 and 220 correspond to monitoring sections used in the related art. It may be understood that the section or time interval denoted by reference numeral 230, which is a monitoring section used in the present disclosure, is considerably wider than those denoted by reference numerals 210 and 220. Therefore, according to an embodiment, it is possible to increase the accuracy of diagnosing the status of the battery 200.

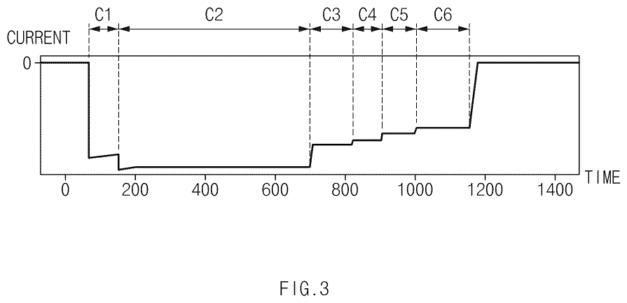

FIG. 3 is a diagram illustrating an example of a current section detected by a controller provided in a device for diagnosing a state of a battery according to an embodiment of the present disclosure.

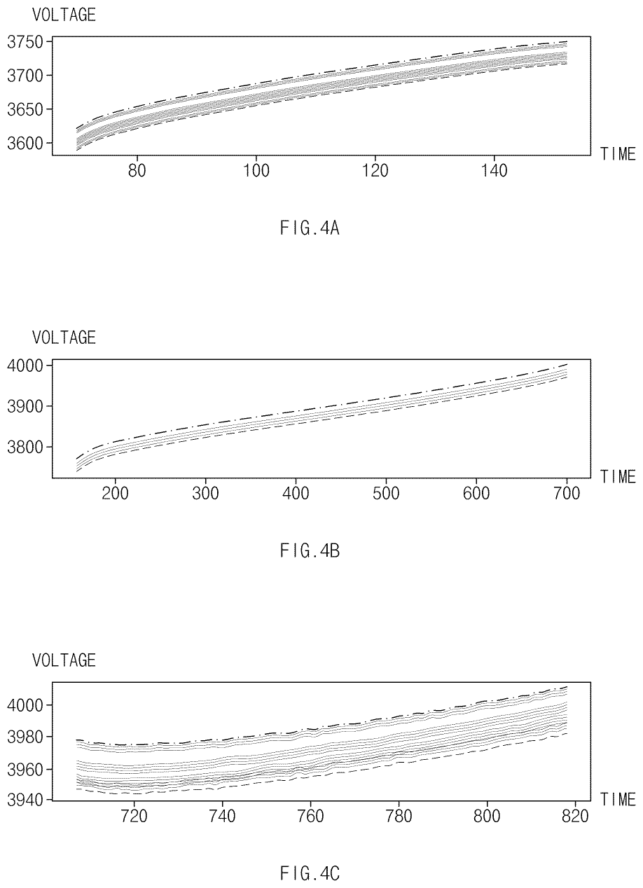

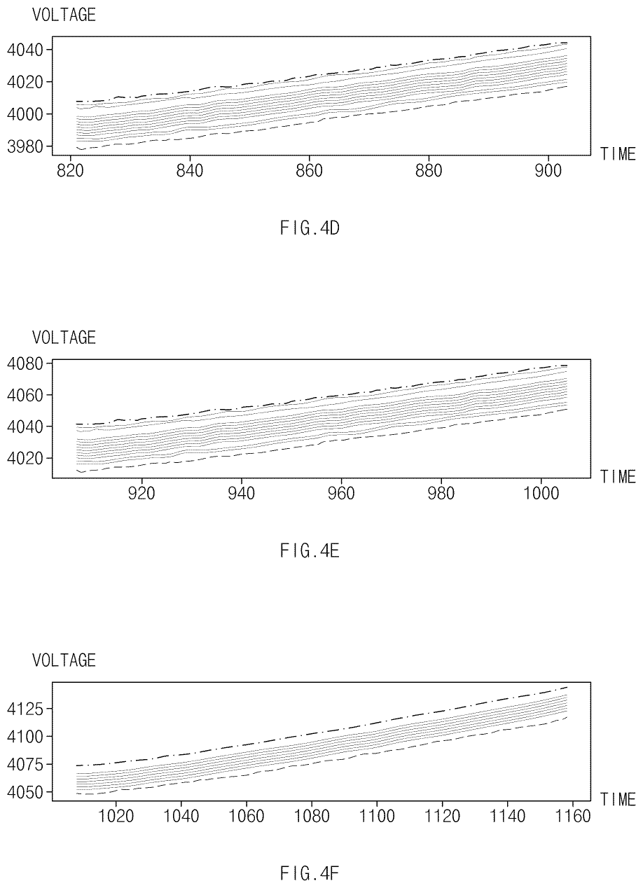

As illustrated in FIG. 3, the controller 50 detects sections C1, C2, C3, C4, C5, and C6 as current sections (e.g., diagnosing time intervals) in which the preset current change value is maintained. In this case, the current change value may be set to a range (e.g., 0 mA to 10 mA). Accordingly, the current section may include a constant current section in which the current change value is ‘0 (zero)’ (i.e., the current stays constant), as well as a current section (i.e., a nearly constant current section) having a slope within a specified range (e.g., 0.05 or less) FIG. 4A is a diagram illustrating the voltage of each cell constituting a battery within current section C1. FIG. 4B is a diagram illustrating the voltage of each cell constituting a battery within current section C2. FIG. 4C is a diagram illustrating the voltage of each cell constituting a battery within current section C3. FIG. 4D is a diagram illustrating the voltage of each cell constituting a battery within current section C4. FIG. 4E is a diagram illustrating the voltage of each cell constituting a battery within current section C5. FIG. 4F is a diagram illustrating the voltage of each cell constituting a battery within current section C6.

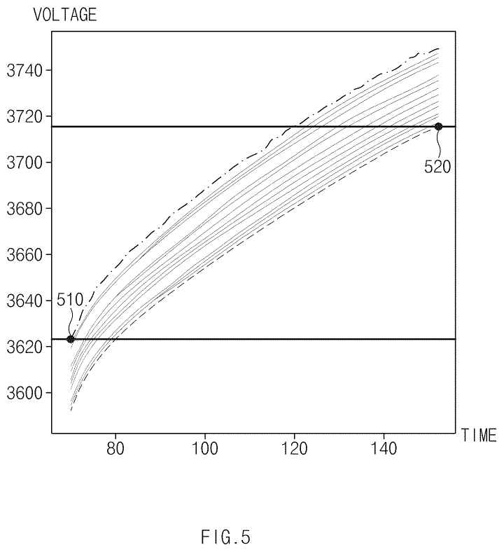

FIG. 5 is a diagram illustrating an operation of determining the minimum voltage and the maximum voltage in current section C1 by a controller provided in a device for diagnosing a state of a battery according to an embodiment of the present disclosure.

As illustrated in FIG. 5, the controller 50 may monitor the voltages of all cells constituting the battery 200 within current section C1 to detect the maximum voltage and minimum voltage of each cell. In addition, the controller 50 may determine the highest or maximum value 510 among the minimum voltages of each cell as the minimum voltage (e.g., 3,715 mV) of current section C1, and may determine the lowest or minimum value 520 among the maximum voltages of each cell as the maximum voltage (e.g., 3,620 mV) of current section C1.

For example, when the minimum voltage of the first cell is a1 and the maximum voltage is b1 within current section C1, the minimum voltage of the second cell is a2 and the maximum voltage is b2, the minimum voltage of the third cell is a3 and the maximum voltage is b3, and a1<a2<a3 and b1<b2<b3 are satisfied, the controller 50 may determine the minimum voltage of current section C1 as a3 and the maximum voltage of current section C1 as b1.

For reference, the minimum voltage in current section C2 is 3,775 mV and the maximum voltage is 3,965 mV. The minimum voltage in current section C3 is 3,975 mV and the maximum voltage is 3,981 mV. The minimum voltage in current section C4 is 4,007 mV and the maximum voltage is 4,016 mV. The minimum voltage in current section C5 is 4,038 mV and the maximum voltage is 4,051 mV. The minimum voltage in current section C6 is 4,073 mV and the maximum voltage is 4,116 mV.

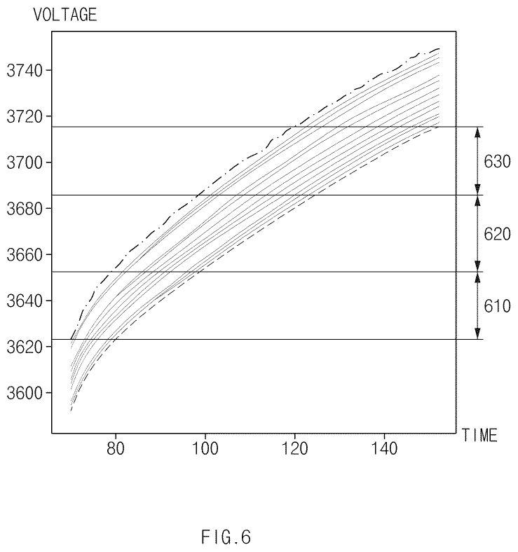

FIG. 6 is a diagram illustrating a result of dividing the voltage range of current section C1 into a plurality of voltage sections by a controller provided in a device for diagnosing a state of a battery according to an embodiment of the present disclosure.

As illustrated in FIG. 6, the controller 50 may divide the voltage range (3,620 mV to 3,715 mV) of current section C1 into, for example, a first voltage section 610, a second voltage section 620, and a third voltage section 630. In this case, the controller 50 may divide the voltage range (3,620 mV to 3,715 mV) of current section C1 into intervals of 5 mV, taking into account the error of the voltage sensor 30. In this case, the voltage range of current section C1 may be divided into a total of 19 voltage sections.

For example, the first voltage section may be 3,620 mV to 3,625 mV, the second voltage section may be 3,625 mV to 3,630 mV, and the third voltage section may be 3,630 mV to 3,635 mV. Accordingly, the controller 50 may determine the minimum voltage of the first voltage section as 3,620 mV and the maximum voltage as 3,625 mV. The controller 50 may determine the minimum voltage of the second voltage section as 3625 mV and the maximum voltage as 3630 mV. In addition, the controller 50 may determine the minimum voltage of the third voltage section as 3,630 mV and the maximum voltage as 3,635 mV.

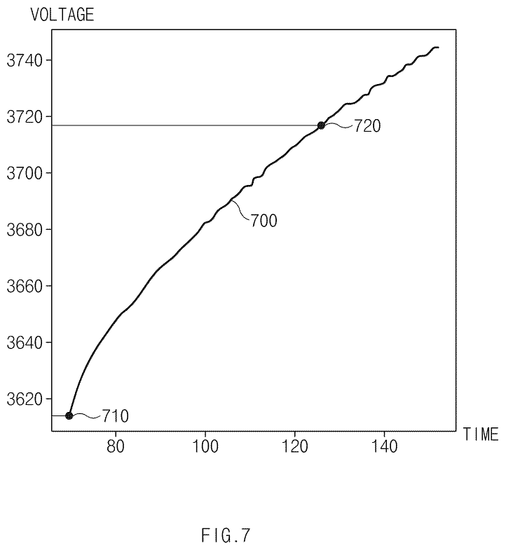

FIG. 7 is a diagram illustrating an example of an operation of detecting a time change value of each cell voltage by a controller provided in a device for diagnosing a state of a battery according to an embodiment of the present disclosure.

In FIG. 7, the horizontal axis represents time(s), the vertical axis represents voltage (mV), reference numeral 700 represents a voltage change graph of cell 1 in current section C1, reference numeral 710 represents the minimum voltage in current section C1, and reference numeral 720 represents the maximum voltage in current section C1.

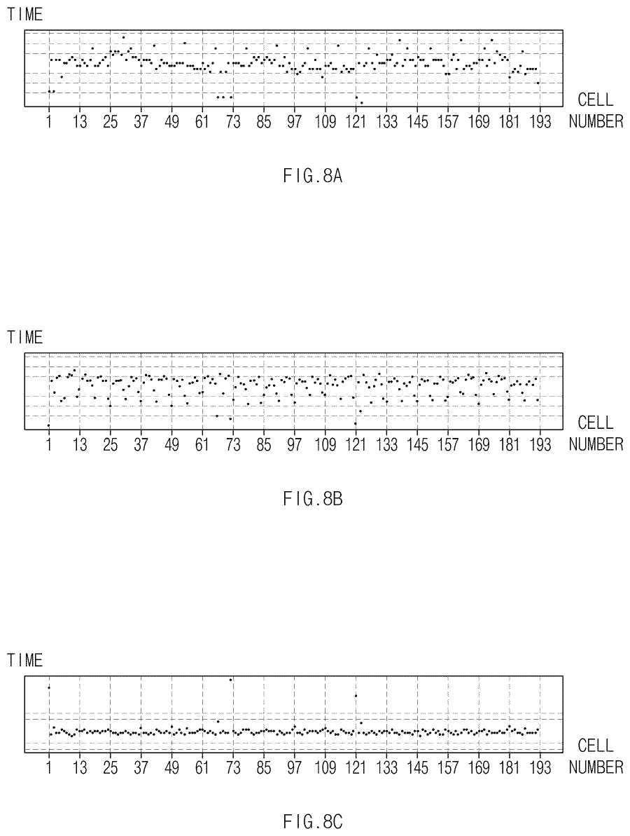

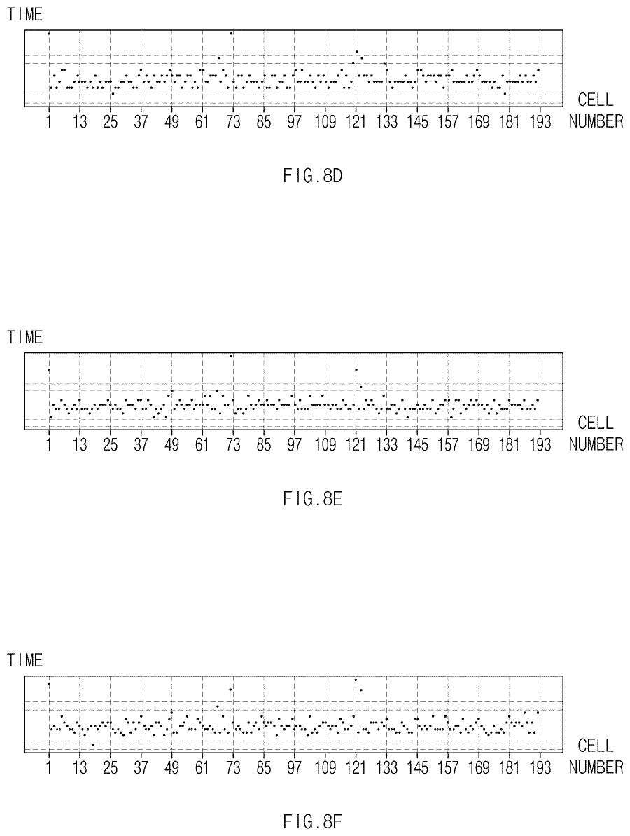

As illustrated in FIG. 7, the controller 50 may detect the time (e.g., 54 seconds) for the voltage of cell 1 to reach the maximum voltage from the minimum voltage. The times detected for all the cells in current section C1 in such a manner are as shown in FIG. 8A.

FIG. 8A is a diagram illustrating the time taken for the voltage of each cell to reach the maximum voltage from the minimum voltage in current section C1, where the horizontal axis represents the cell number and the vertical axis represents time.

In addition, FIG. 8B is a diagram illustrating the time taken for the voltage of each cell to reach the maximum voltage from the minimum voltage in current section C2. FIG. 8C is a diagram illustrating the time taken for the voltage of each cell to reach the maximum voltage from the minimum voltage in current section C3. FIG. 8D is a diagram illustrating the time taken for the voltage of each cell to reach the maximum voltage from the minimum voltage in current section C4. FIG. 8E is a diagram illustrating the time taken for the voltage of each cell to reach the maximum voltage from the minimum voltage in current section C5. FIG. 8F is a diagram illustrating the time taken for the voltage of each cell to reach the maximum voltage from the minimum voltage in current section C6.

In addition, when the voltage range of current section C1 is divided into voltage intervals of 5 mv, the controller 50 may generate 19 different frequency distributions in current section C1. This is a case where the voltage range is subdivided and may be used for more accurate diagnosis.

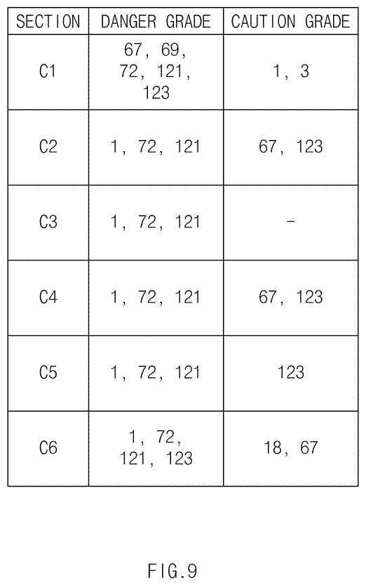

FIG. 9 is a diagram illustrating cells classified by grade by a controller provided in a device for diagnosing a state of a battery according to an embodiment of the present disclosure.

The controller 50 may determine the standard deviation (σ) of times corresponding to each cell in current section C1 as illustrated in FIG. 8A, determine the cells included in the first threshold section (−3σ to −2σ and 2σ to 3σ) as a caution grade, and determine the cells included in the second threshold section (less than −3σ and greater than 3σ) as a danger grade.

The controller 50 may determine the standard deviation (σ) of times corresponding to each cell in current section C2 as illustrated in FIG. 8B, determine the cells included in the first threshold section (−3σ to −2σ and 2σ to 3σ) as a caution grade, and determine the cells included in the second threshold section (less than −3σ and greater than 3σ) as a danger grade.

The controller 50 may determine the standard deviation (σ) of times corresponding to each cell in current section C3 as illustrated in FIG. 8C, determine the cells included in the first threshold section (−3σ to −2σ and 2σ to 3σ) as a caution grade, and determine the cells included in the second threshold section (less than −3σ and greater than 3σ) as a danger grade.

The controller 50 may determine the standard deviation (σ) of times corresponding to each cell in current section C4 as illustrated in FIG. 8D, determine the cells included in the first threshold section (−3σ to −2σ and 2σ to 3σ) as a caution grade, and determine the cells included in the second threshold section (less than −3σ and greater than 3σ) as a danger grade.

The controller 50 may determine the standard deviation (σ) of times corresponding to each cell in current section C5 as illustrated in FIG. 8E, determine the cells included in the first threshold section (−3σ to −2σ and 2σ to 3σ) as a caution grade, and determine the cells included in the second threshold section (less than −3σ and greater than 3σ) as a danger grade.

The controller 50 may determine the standard deviation (σ) of times corresponding to each cell in current section C6 as illustrated in FIG. 8F, determine the cells included in the first threshold section (−3σ to −2σ and 2σ to 3σ) as a caution grade, and determine the cells included in the second threshold section (less than −3σ and greater than 3σ) as a danger grade.

Therefore, the controller 50 may generate a table in which cells by grade are described as shown in FIG. 9.

The controller 50 may diagnose the state of the battery 200 based on the number of cells included in the threshold section (e.g., −2σ or less and 2σ or more). For example, when the number of cells included in the threshold section exceeds a reference number (e.g., 5 or more), the controller 50 may diagnose the state of the battery 200 as abnormal.

In addition, when the number of cells included in the second threshold section (less than −3σ and greater than 3σ) exceeds the reference number, the controller 50 may diagnose the state of the battery 200 as abnormal.

In addition, when a cell included in the second threshold section (less than −3σ and greater than 3σ) is detected repeatedly in multiple current sections, the controller 50 may diagnose the state of the battery 200 as abnormal.

In addition, when a cell classified as a dangerous grade (e.g., cell number 121) is detected in all current sections (C1 to C6), the controller 50 may provide a message instructing replacement of the battery 200 through the display 40.

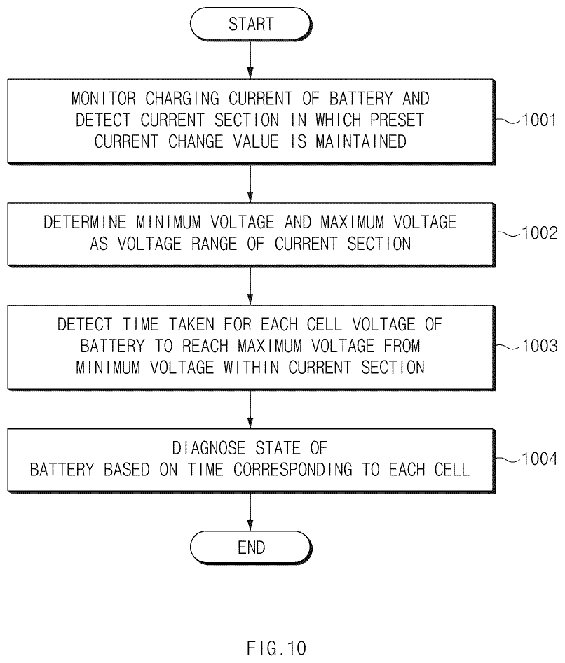

FIG. 10 is a flowchart illustrating a method of diagnosing a state of a battery according to one embodiment of the present disclosure.

First, in 1001, the controller 50 monitors the charging current of the battery 200 and detects a current section in which a preset current change value is maintained.

Then, in 1002, the controller 50 determines the minimum (or first) voltage and the maximum (or second) voltage as the voltage range of the current section.

Then, in 1003, the controller 50 detects the time taken for each cell voltage of the battery 200 to reach the maximum voltage from the minimum voltage within the current section.

Then, in 1004, the controller 50 diagnoses the state of the battery 200 based on the time corresponding to each cell.

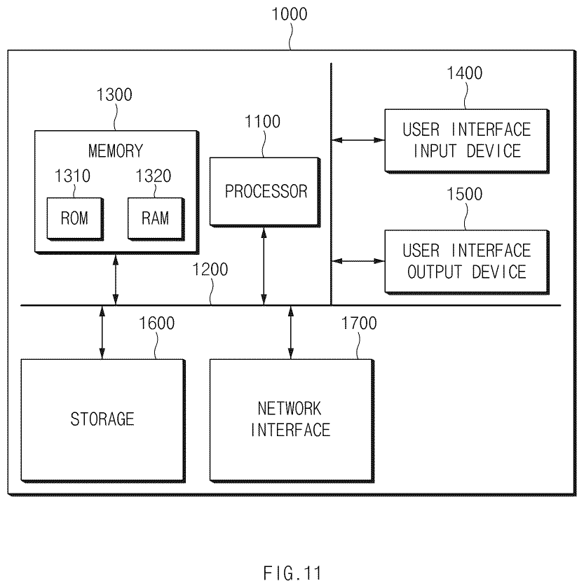

FIG. 11 is a block diagram illustrating a computing system for executing a method of diagnosing a state of a battery according to each embodiment of the present disclosure.

Referring to FIG. 11, as described above, the method of diagnosing a state of a battery according to an embodiment of the present disclosure may be implemented through a computing system 1000. The computing system 1000 may include at least one processor 1100, a memory 1300, a user interface input device 1400, a user interface output device 1500, storage 1600, and a network interface 1700 which are connected through a system bus 1200.

The processor 1100 may be a central processing unit (CPU) or a semiconductor device that processes instructions stored in the memory 1300 and/or the storage 1600. The memory 1300 and the storage 1600 may include various volatile or nonvolatile storage media. For example, the memory 1300 may include a read only memory (ROM) 1310 and a random access memory (RAM) 1320.

Accordingly, the processes of the method or algorithm described in relation to embodiments of the present disclosure may be implemented directly by hardware executed by the processor 1100, a software module, or a combination thereof. The software module may reside in a storage medium (i.e., the memory 1300 and/or the storage 1600), such as a RAM, a flash memory, a ROM, an EPROM, an EEPROM, a register, a hard disk, a detachable disk, or a CD-ROM. In one example, the storage medium is coupled to the processor 1100, and the processor 1100 may read information from the storage medium and may write information in the storage medium. In another method, the storage medium may be integrated with the processor 1100. The processor 1100 and the storage medium may reside in an application specific integrated circuit (ASIC). The ASIC may reside in a user terminal. In another method, the processor 1100 and the storage medium may reside in the user terminal as an individual component.

According to embodiments of the present disclosure, it is possible to accurately diagnose not only the state of a battery but also the state of each cell constituting the battery by monitoring the charging current of the battery to detect a current section in which a preset current change value is maintained, determining the minimum voltage and the maximum voltage in the current section, detecting the time taken for each cell voltage of the battery to reach the maximum voltage from the minimum voltage within the current section, and diagnosing the state of the battery based on the time corresponding to each cell.

The above-described techniques, devices, methods, and/or systems implementing such techniques, can further include battery management based at least in part upon the above techniques. For instance, devices and/or methods according to embodiments of the present disclosure may manage a battery based at least in part a diagnosis result of the state of the battery diagnosed using the above-described devices and/or methods. For example, such battery management may control cells of the battery and/or may perform cell balancing to maintain balance between the cells of the battery based on a diagnosis result of the state of the battery obtained using the above-described devices and/or methods.

The above description is a simple exemplification of the technical spirit of the present disclosure, and the present disclosure may be variously corrected and modified by those having ordinary skill in the art to which the present disclosure pertains without departing from the essential features of the present disclosure. Therefore, the disclosed embodiments of the present disclosure do not limit the technical spirit of the present disclosure but are illustrative, and the scope of the technical spirit of the present disclosure is not limited by embodiments of the present disclosure. The scope of the present disclosure should be construed by the claims, and it should be understood that all the technical spirits within the equivalent range fall within the scope of the present disclosure.

What is claimed is:

1. A device for diagnosing a state of a battery, the device comprising:
a current sensor configured to determine a charging current of the battery;
a voltage sensor configured to determine a voltage of the battery; and
a controller configured to
monitor the charging current of the battery to determine a diagnosing time interval in which a preset current change value is maintained,
determine a first voltage and a second voltage as a voltage range of the diagnosing time interval,
determine a time taken for each cell voltage of each cell of a plurality of cells of the battery to reach the second voltage from the first voltage within the diagnosing time interval, and
diagnose the state of the battery based on the time corresponding to each cell.

2. The device of claim 1, wherein the controller is further configured to
determine a maximum voltage and a minimum voltage of each cell in the diagnosing time interval,
determine a highest value among minimum voltages of the plurality of cells as the first voltage of the diagnosing time interval, and
determine a lowest value among maximum voltages of the plurality of cells as the second voltage of the diagnosing time interval.

3. The device of claim 1, wherein the controller is further configured to
determine a standard deviation of times corresponding to the plurality of cells, and
diagnose the state of the battery based on the standard deviation.

4. The device of claim 1, wherein the controller is further configured to
determine a plurality of diagnosing time intervals,
determine a first voltage and a second voltage in each diagnosing time interval,
determine a time taken for each cell voltage to reach the second voltage from the first voltage within each diagnosing time interval, and
diagnose the state of the battery based on the time corresponding to each cell in each diagnosing time interval of the plurality of diagnosing time intervals.

5. The device of claim 4, wherein the controller is further configured to
determine a standard deviation of times corresponding to the plurality of cells in each diagnosing time interval, and
diagnose the state of the battery based on the standard deviation of each diagnosing time interval.

6. The device of claim 1, wherein the controller is further configured to
divide the voltage range into a plurality of voltage segments,
determine a voltage segment time taken for each cell voltage to reach a maximum voltage from a minimum voltage within each voltage segment, and
diagnose the state of the battery based on the voltage segment time corresponding to each cell in each voltage segment.

7. The device of claim 6, wherein the controller is further configured to
determine a standard deviation of voltage segment times corresponding to the plurality of cells in each voltage segment, and
diagnose the state of the battery based on the standard deviation of each voltage segment.

8. The device of claim 1, wherein the controller is further configured to monitor the charging current of the battery in all time intervals other than a time interval of a state transition between a closed circuit voltage (CCV) and an open circuit voltage (OCV).

9. The device of claim 1, wherein the controller is further configured to determine a time interval of a constant current in which a current change value is 0 (zero) as the diagnosing time interval.

10. A method of diagnosing a state of a battery, the method comprising:
determining, by a controller, a diagnosing time interval in which a preset current change value is maintained, by monitoring a charging current of the battery;
determining, by the controller, a first voltage and a second voltage as a voltage range of the diagnosing time interval;
determining, by the controller, a time taken for each cell voltage of each cell of a plurality of cells of the battery to reach the second voltage from the first voltage within the diagnosing time interval; and
diagnosing, by the controller, the state of the battery based on the time corresponding to each cell.

11. The method of claim 10, wherein determining the first voltage and the second voltage includes:
determining a maximum voltage and a minimum voltage of each cell in the diagnosing time interval;
determining a highest value among minimum voltages of the plurality of cells as the first voltage of the diagnosing time interval; and
determining a lowest value among maximum voltages of the plurality of cells as the second voltage of the diagnosing time interval.

12. The method of claim 10, wherein diagnosing the state of the battery includes:
determining a standard deviation of times corresponding to the plurality of cells; and
diagnosing the state of the battery based on the standard deviation.

13. The method of claim 10, wherein diagnosing the state of the battery includes diagnosing the state of the battery based on a time corresponding to each cell in each diagnosing time interval of a plurality of diagnosing time intervals based on determining the plurality of diagnosing time intervals.

14. The method of claim 13, wherein diagnosing the state of the battery includes:
determining a standard deviation of times corresponding to each cell in each diagnosing time interval; and
diagnosing the state of the battery based on the standard deviation of each diagnosing time interval.

15. The method of claim 10, wherein diagnosing the state of the battery includes:
diagnosing the state of the battery based on a voltage segment time corresponding to each cell in each of a plurality of voltage segments based on dividing the voltage range into the plurality of voltage segments.

16. The method of claim 15, wherein diagnosing the state of the battery includes:
determining a standard deviation of times corresponding to the plurality of cells in each voltage segment; and
diagnosing the state of the battery based on the standard deviation of each voltage segment.

17. The method of claim 10, wherein determining the diagnosing time interval includes monitoring the charging current of the battery in all time intervals other than a time interval of a state transition between a closed circuit voltage (CCV) and an open circuit voltage (OCV).

18. The method of claim 10, wherein determining the diagnosing time interval includes determining a time interval of a constant current in which a current change value is 0 (zero) as the diagnosing time interval.
